(19) United States
(12) Patent Application Publication
(10) Pub. No.: US 2011/0049727 A1
(43) Pub. Date: Mar. 3, 2011

(54) RECESSED INTERLAYER DIELECTRIC IN A METALLIZATION STRUCTURE OF A SEMICONDUCTOR DEVICE

(76) Inventors: Oliver Aubel, Dresden (DE); Frank Feustel, Dresden (DE); Christian Hennesthal, Niederau (DE)

(21) Appl. No.: 12/854,441

(22) Filed: Aug. 11, 2010

(30) Foreign Application Priority Data
Aug. 31, 2009 (DE) 10 2009 039 416.8

(51) Int. Cl. H01L 23/522; H01L 21/768

(52) U.S. Cl. 257/773; 438/622; 257/E21.575; 257/E23.142

(57) ABSTRACT

In a complex metallization system, the probability of dielectric breakdown may be reduced by vertically separating a critical area of high electric field strength and an area of reduced dielectric strength of the interlayer dielectric material. For this purpose, the interlayer dielectric material may be recessed after forming the metal regions and/or the metal regions may be increased in height and the corresponding recess may be refilled with an appropriate dielectric material.

### BACKGROUND OF THE INVENTION

1. Field of the Invention

Generally, the present disclosure relates to semiconductor devices, such as integrated circuits, and, more particularly, to the metallization layers including closely spaced conductive metal lines embedded in a dielectric material.

2. Description of the Related Art

In modern integrated circuits, minimum feature sizes, such as the channel length of field effect transistors, have reached the deep sub-micron range, thereby steadily increasing performance of these circuits in terms of speed and/or power consumption and/or diversity of circuit functions. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines and the spaces between the metal lines have to be reduced to compensate for a reduced amount of available floor space and for an increased number of circuit elements provided per unit area.

In integrated circuits having minimum dimensions of approximately 0.35 μm and less, a limiting factor of device performance is the signal propagation delay caused by the switching speed of the transistor elements. As the channel length of these transistor elements has now reached 50 nm and less, the signal propagation delay is no longer limited by the field effect transistors but is limited, owing to the increased circuit density, by the interconnect lines, since the line-to-line capacitance (C) is increased and also the resistance (R) of the lines is increased due to their reduced cross-sectional area. The parasitic RC time constants and the capacitive coupling between neighboring metal lines have, therefore, initiated the introduction of a new type of material for forming the metallization layer.

In sophisticated applications, the well-known and well-established metal aluminum is increasingly being replaced by metals of superior electrical conductivity, such as copper, copper alloys and the like, which may allow significantly higher current densities in the metal lines and vias compared to aluminum. Consequently, the cross-sectional area of the metal lines may be reduced compared to aluminum-based metallization systems, thereby providing an increased packing density. On the other hand, upon reducing the lateral dimensions in the metallization system, the spacing between neighboring metal lines also has to be reduced, which in turn negatively influences the parasitic capacitance when using well-established dielectric materials, such as silicon dioxide and silicon nitride. For this reason, dielectric material systems have been developed in an attempt to further reduce the dielectric constant with a value of 3.0 and less, which may hereinafter be referred to as low-k dielectric materials. For example, a plurality of polymer materials, silicon oxide-based materials including organic components and the like have been proven viable dielectric materials for forming sophisticated metallization systems of semiconductor devices. In many approaches, a low value of the dielectric constant may be achieved by further reducing the density of appropriate materials, for instance by incorporating organic compounds, which may subsequently be “driven” out of the dielectric material on the basis of appropriate treatments, such as heat treatment, UV treatment and the like. Consequently, a specific density of voids or nano cavities is generated in the dielectric material, thereby significantly reducing the dielectric constant of the base material. Although significant progress has been achieved by using copper in combination with low-k dielectric material with respect to packing density in the metallization system while providing a certain required electrical performance, it turns out that, upon further device scaling, significant yield losses and/or reduced reliability or premature failure of the devices, in particular in the metallization system, may be observed, which may be caused by dielectric breakdown of the sensitive low-k dielectric materials.

It is well known that low-k dielectric materials may be associated with reduced chemical and mechanical stability compared to conventional dielectrics, such as silicon dioxide and silicon nitride, which may negatively affect the manufacturing process and the characteristics of the finished semiconductor device. For instance, due to copper's characteristics, i.e., not forming volatile etch byproducts during typical plasma assisted etch atmospheres and the non-availability of efficient deposition techniques with high deposition rates based on chemical vapor deposition (CVD) processes, the integration scheme for forming sophisticated metallization systems may be based on the deposition of an appropriate dielectric material system and patterning the same in order to form trenches and/or openings for vias, which may subsequently be individually or commonly filled with copper in combination with conductive barrier materials, which are typically necessary due to the high diffusion rate of copper in a plurality of dielectric materials. Furthermore, the deposition of the copper fill material may typically be accomplished by using electrochemical deposition techniques, wherein any excess metal of the copper and of the conductive barrier materials has to be removed in order to obtain the isolated metal regions. During the removal of the excess metal, which is typically based on a chemical mechanical polishing (CMP) process, significant chemical and mechanical stress may be imposed on the sensitive dielectric material which may result, in combination with the geometric configuration of the metallization system, in high yield loss and reduced reliability, as will be explained in more detail with reference to FIGS. 1a and 1b.

FIG. 1a schematically illustrates a cross-sectional view of a semiconductor device 100 which may represent any sophisticated semiconductor device, such as a CPU, a memory chip, a mixed signal system and the like, in which a sophisticated metallization system on the basis of a highly conductive metal and a low-k dielectric material is required. The device 100 comprises a substrate 101 which represents any appropriate carrier material for forming therein and thereabove circuit elements, such as transistors, capacitors, resistors and the like. For convenience, any such circuit elements are not shown in FIG. 1a. As previously discussed, critical dimensions of the circuit elements may be 100 nm and significantly less, thereby providing a high packing density in the device level, which may thus also require a high density of metal interconnect structures in a metallization system 150 of the device 100. Depending on the overall complexity of the semiconductor device 100, typically, a plurality of stacked metallization layers 120, 130 are provided in the metallization system 150, wherein, for convenience, only two of these metallization layers are illustrated in FIG. 1a. The metallization layer 120 may comprise a dielectric material 121, which may be provided as any appropriate material, wherein, as explained above, in sophisticated applications, at least a portion of the dielectric material 121 may comprise a low-k dielectric material having a dielectric constant of 3.0 or less. It should be appreciated that the dielectric constant of a dielectric material may be readily determined on the basis of well-established measurement techniques, for instance, by providing a well-defined capacitive structure and obtaining the frequency response of the capacitive structure for a well-defined initial signal. From the frequency response, the dielectric constant may then be determined on the basis of well-established algorithms. Furthermore, metal lines 122 are embedded in the dielectric material 121 and typically comprise a conductive barrier material 122A, for instance in the form of tantalum, tantalum nitride, titanium, titanium nitride and the like, which may provide superior adhesion of a core material 122B, for instance a copper material, to the dielectric material 121 and which may also provide superior confinement of the core metal 122B as, for instance, copper may readily diffuse in silicon dioxide, silicon oxide-based materials and many low-k dielectric materials. Furthermore, a dielectric cap layer 123 is formed on the dielectric material 121 and on the metal regions 122, wherein the layer 123 may provide etch stop capabilities during the further processing of the device and may also impart superior stability to the sensitive material 121 and may confine the core material 122B. For instance, silicon nitride has copper diffusion blocking abilities and may also act as an efficient etch stop material for a plurality of well-established etch recipes. In other cases, the etch stop layer 123 may be provided in the form of other materials, such as nitrogen-containing silicon carbide, dielectric silicon carbide and the like, when the dielectric constant of a silicon nitride material is considered inappropriate.

Similarly, the metallization layer 130 comprises a dielectric material 131 and metal regions 132, which in turn may comprise a conductive barrier material 132A and a core metal 132B. The metal regions 132 as illustrated may represent metal lines in an upper portion of the dielectric material 131, as indicated by 132M, and may be connected to the underlying metallization layer 120 by vias 132V in accordance with the circuit layout. As previously discussed, a width of the metal lines 132M may be in the range of 100 nm and less, depending on the metallization level under consideration and the critical dimensions in the device level. Thus, also a spacing 130W between adjacent metal lines 132M at a surface 131S of the dielectric material 131 may be in the range of 100 nm and less.

The semiconductor device 100 as illustrated in FIG. 1 a may be formed on the basis of the following process techniques. After manufacturing any circuit elements, such as transistors and the like, in and above a semiconductor material that is formed in and above the substrate 101, a contact level (not shown) is typically provided by embedding the circuit elements in a dielectric material and forming vertical contacts through the dielectric material in order to connect corresponding contact areas, such as drain and source regions of field effect transistors, gate electrode structures, resistors, capacitor electrodes and the like. The contact level may thus act as an interface between the actual semiconductor elements and the metallization system 150. Thereafter, one or more metallization layers may be formed, such as the layer 120, wherein manufacturing techniques may be applied as will be explained with reference to the metallization layer 130. That is, after depositing the etch stop or cap material 123 on the dielectric material 121 and the metal regions 122, one or more dielectric materials may be deposited, wherein, in the example shown, a low-k dielectric material may be formed, at least in a portion that corresponds to the metal lines 132M. For this purpose, CVD techniques, spin-on techniques and the like are available wherein, as previously discussed, additional treatments may be performed so as to further reduce the dielectric constant which, however, may be associated with a further reduction of at least the chemical stability of the resulting material. Thereafter, any further materials, such as hard mask materials, if required, anti-reflective coating (ARC) material and the like, may be formed in combination with a resist material so that an appropriate etch mask may be provided, for instance, for defining the lateral size and position of the vias 132V or the metal lines 132M, depending on the process strategy used. In the following, it may be assumed that the dielectric layer 131 may be patterned so as to receive openings and trenches for the components 132M, 132V, which may then be filled in a common deposition process. In other approaches, the vias 132V may be formed separately in a first portion of the dielectric material 131 and thereafter the second portion may be deposited and may be patterned so as to obtain trenches for the metal lines 132M. After the patterning of the dielectric material 131, which may also be associated with a certain degree of damaging, the material 131, i.e., surface portions thereof may be exposed to reactive process atmospheres, such as etch processes, resist stripping processes, cleaning processes and the like. Next, the conductive barrier material 132A is deposited, for instance by sputter deposition and the like, depending on the material composition and the device requirements. Next, a seed layer, if required, may be deposited, such as a copper layer, which may be accomplished by sputter deposition. Thereafter, the actual core material 132B is deposited by electrochemical deposition techniques, such as electroplating or electroless plating. During this deposition process, a significant “over filling” may be required so as to reliably fill the trenches and openings in the dielectric material 131. Thereafter, any excess material is removed, for instance on the basis of CMP, electro CMP, electro etching and the like. Typically at least one CMP process may be involved in removing the excess material, thereby inducing stress in the dielectric material 131, which may result in a certain degree of damaging, at least in the vicinity of the surface 131S. For example, the mechanical stress may create tiny cracks in the surface 131S, which may increase in size and may be contaminated during the polishing process by any metal residues, thereby significantly reducing an initial dielectric strength of the material 131.

FIG. 1b schematically illustrates the semiconductor device 100 in a further advanced manufacturing stage in which an etch stop layer or cap layer 133 is formed on the dielectric material 131 and the copper regions 132. As illustrated, the material 133 may thus cover a damaged surface layer 131A, which may include any damage caused by preceding manufacturing processes, such as CMP, so that the dielectric strength of the layer 131A may be significantly less compared with the initial dielectric strength of the material 131. At the same time, an area of maximum electric field 134 may also be positioned in or at least in immediate proximity to the surface layer 131A so that the probability of a dielectric breakdown may significantly increase, in particular when the distance 130W is reduced in order to enhance packing density in the metallization system 150. Consequently, significant yield loss or premature failures of the metallization system may be observed in sophisticated semiconductor devices.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and process techniques in which the probability of dielectric breakdown events in the metallization system of sophisticated semiconductor devices may be reduced by “positioning” the area of maximum electric field strength of metal lines outside a portion of the dielectric material that may have a significantly reduced dielectric strength, for instance due to any damage caused during the preceding manufacturing process and the like. To this end, in some illustrative embodiments, the dielectric material may be recessed with respect to adjacent metal regions and the recesses may be refilled with a dielectric material having a superior dielectric strength compared to a portion of the initial dielectric material. The fill material for the recess may represent any appropriate material, such as the dielectric material of a next metallization layer, an etch stop material and the like. In other cases, a dedicated material or material system may be provided in the recess in order to locally increase the dielectric strength, without unduly affecting the overall capacitive behavior of the metallization layer under consideration. In still other illustrative embodiments, the location of maximum electrical field strength may be separated from a material portion having a reduced dielectric strength by selectively depositing an additional metal material and filling the resulting “recesses” in the initial dielectric material with any appropriate dielectric material.

One illustrative method disclosed herein relates to forming a metallization system of a semiconductor device. The method comprises removing excess metal from a first dielectric material of a metallization layer by performing a planarization process so as to form insulated metal regions in the dielectric material. The method further comprises removing at least a damaged portion of the dielectric material selectively to the insulated metal regions in order to form a recess adjacent to each of the insulated metal regions. Finally, the recess is filled with a second dielectric material.

A further illustrative method disclosed herein comprises forming a recess between a first metal line and a second metal line, which are formed in a first dielectric material of a first metallization layer of a semiconductor device and which comprise a conductive barrier material and a core metal. The method further comprises filling the recess with a dielectric material and forming a second dielectric material of a second metallization layer above the first metallization layer.

One illustrative semiconductor device disclosed herein comprises a plurality of metal regions that are formed partially in a first dielectric material of a metallization layer, wherein the metal regions have a core metal with a top surface that is positioned at a first height level and wherein the first dielectric material extends to a second height level that is less than the first height level. The semiconductor device further comprises an etch stop material formed on the first dielectric material and on the plurality of metal regions. Furthermore, a second dielectric material is formed on the etch stop material and has a bottom surface at a third height level that is less than the first height level.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a sophisticated semiconductor device formed on the basis of conventional process techniques for providing a complex metallization system;

FIGS. 2a-2c schematically illustrate cross-sectional views of a semiconductor device during various manufacturing stages in forming a metallization system with superior dielectric strength, according to illustrative embodiments;

FIG. 2d schematically illustrates the semiconductor device in which a conductive cap material may be formed prior to removing a damaged portion of a sensitive dielectric material, according to illustrative embodiments;

FIGS. 2e-2j schematically illustrate cross-sectional views of the semiconductor device in which “sidewall spacers” may be formed on exposed upper sidewall portions of metal lines and vias after removing a damaged portion of the sensitive dielectric material, according to further illustrative embodiments;

FIG. 2k schematically illustrates a cross-sectional view of the semiconductor device in which a “recess” may be formed by selectively increasing a height of metal lines, according to further illustrative embodiments; and

FIGS. 2l-2m schematically illustrate a top view and a cross-sectional view, respectively, of the semiconductor device in which superior reliability may be accomplished, even for a significant misalignment of metal lines, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides devices and manufacturing techniques in which dielectric breakdown failures in complex metallization systems may be reduced by “separating” the point of maximum electrical field strength and the position of minimum dielectric strength of a dielectric material. For this purpose, a difference in height level between a top surface of metal lines and a surface area of a dielectric material having a minimum dielectric strength may be introduced, wherein a resulting “recess” may be refilled with any appropriate dielectric material, such as a low-k dielectric material, which, however, may have a superior dielectric strength as this material may not be exposed to undue mechanical stress. In other cases, specific materials of superior dielectric strength may be at least partially formed in the recess, thereby even further enhancing the overall dielectric behavior of the metallization system, thereby tolerating alignment inaccuracies without resulting in a premature device failure. In some illustrative embodiments, in particular, a dedicated material may be locally formed at the locations of maximum electrical field strength, for instance in the form of sidewall spacers, while the remaining recess may be filled with any other appropriate dielectric material, such as the low-k dielectric material of the subsequent metallization layer. In still other illustrative embodiments, the separation of the location of critical electrical field strength and a damaged surface portion of the dielectric material may be accomplished by selectively increasing the height of the metal regions, for instance by selectively depositing a portion of the core metal, for instance in the form of copper, copper alloys, silver and the like, which may subsequently be covered by a conductive cap layer or a dielectric etch stop material.

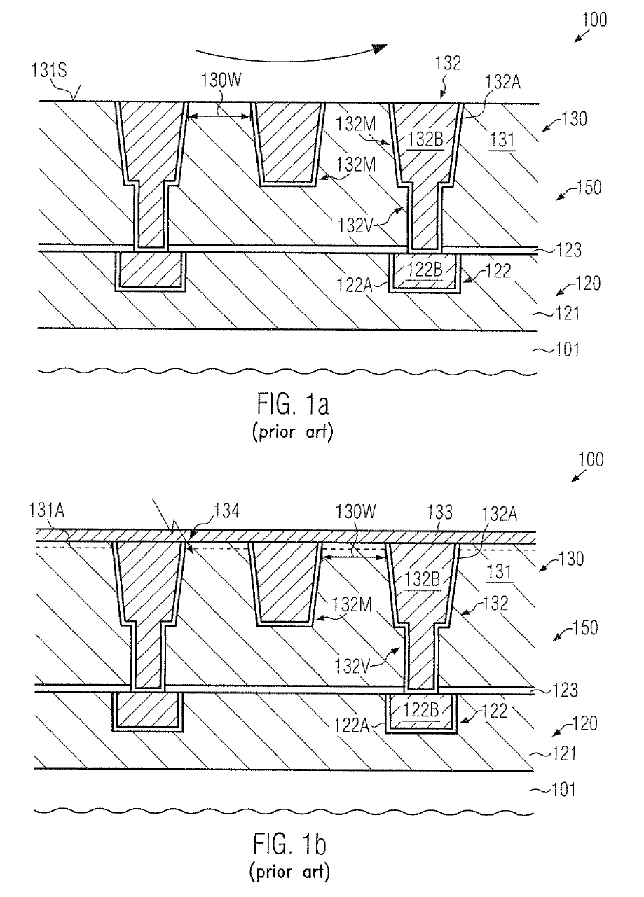

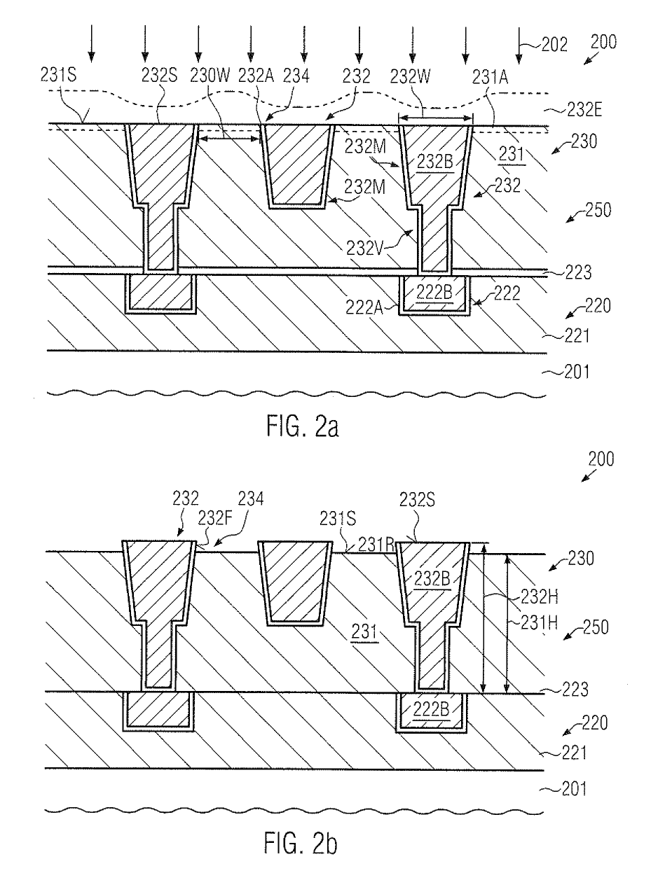

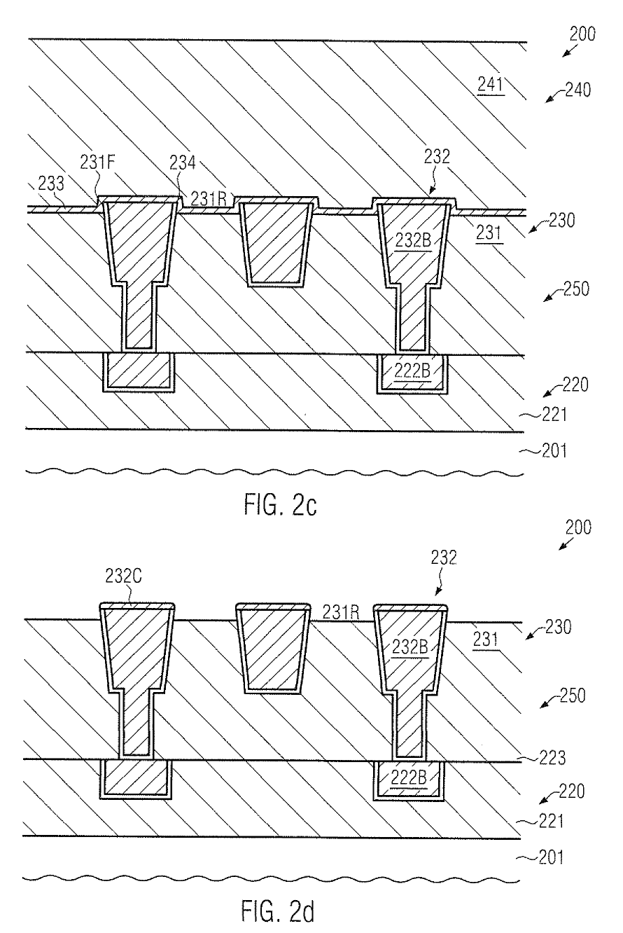

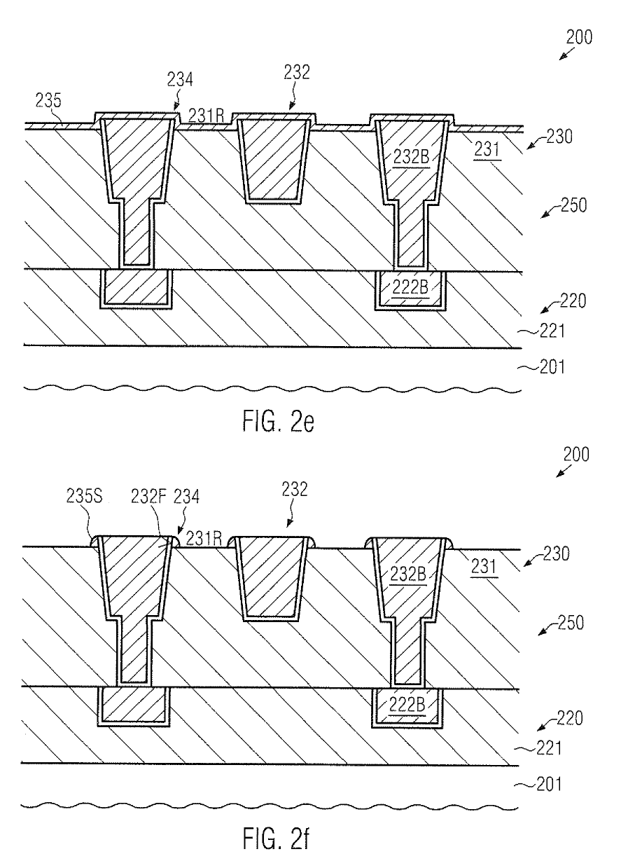

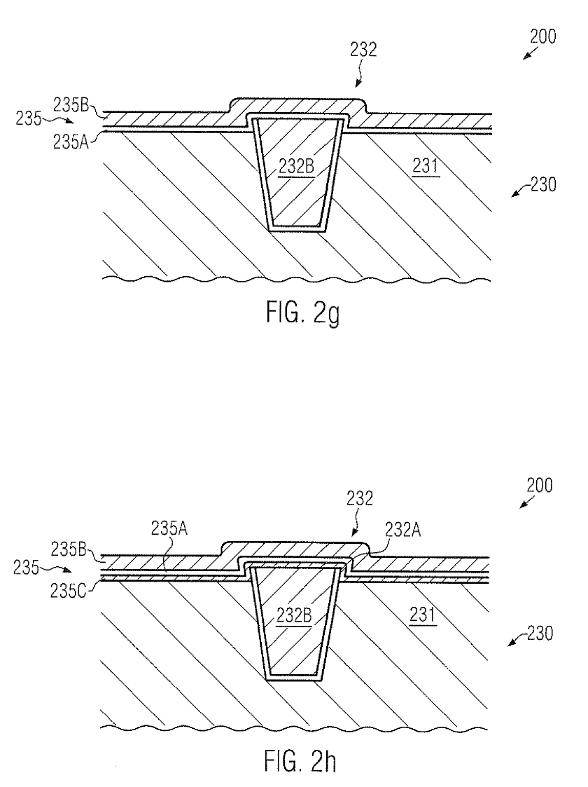

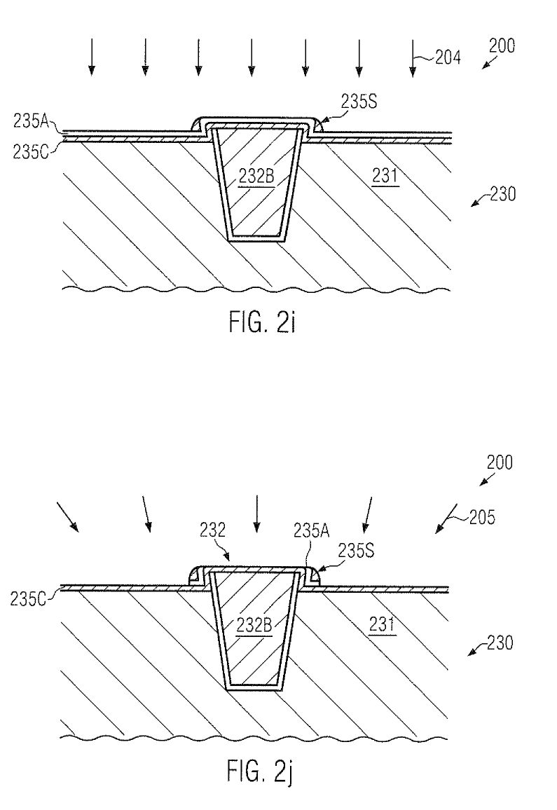

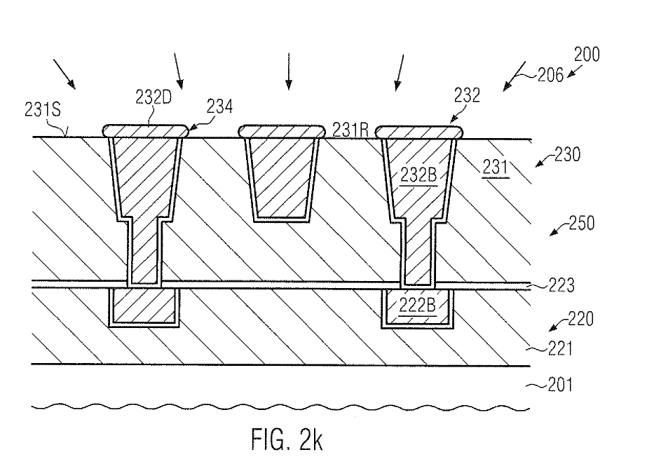

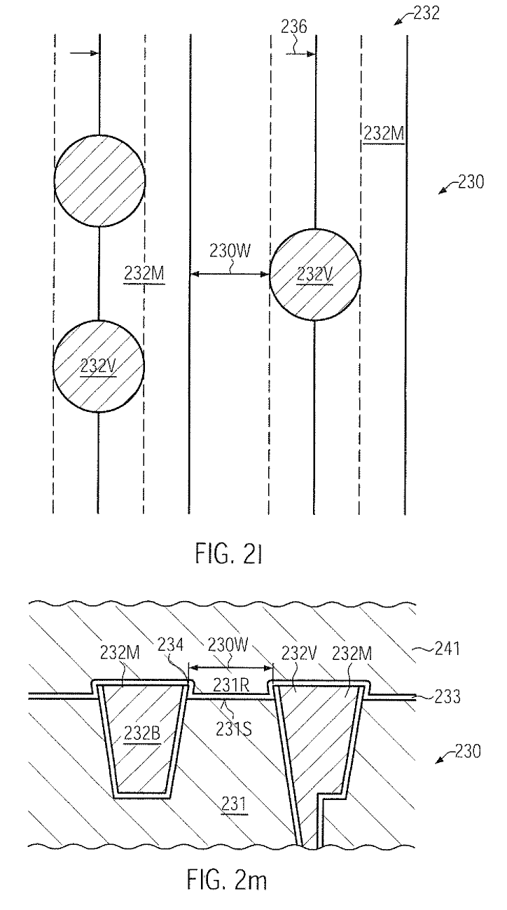

With reference to FIGS. 2a-2m, further illustrative embodiments will now be described in more detail, wherein reference may also be made to FIGS. 1a-1b, if appropriate.

FIG. 2a schematically illustrates a cross-sectional view of a semiconductor device 200 comprising a substrate 201, above which may be formed a metallization system 250. As previously discussed with reference to the device 100, the substrate 201 may have formed therein or thereabove circuit elements, such as transistors and the like, in accordance with the requirements of the device 200. For example, transistor elements with critical dimensions of 50 nm and less may be provided in and above the substrate 201, when sophisticated semiconductor devices are considered. In other cases, the metallization system 250 may be formed above any appropriate substrate without requiring the provision of additional circuit elements, if considered appropriate. The metallization system 250 may comprise a plurality of metallization layers, such as metallization layers 220 and 230, as is also previously discussed. The metallization layer 220 may comprise a dielectric material 221, for instance in the form of a low-k dielectric material, a conventional dielectric material or any combination thereof, depending on the specific configuration of the metallization layer 220. Metal regions 222 may be formed in the dielectric material 221 and may comprise a highly conductive metal 222B, possibly in combination with a conductive barrier material 222A. For instance, the metal 222B, which may also be referred to as a core metal, may be provided in the form of copper, silver, gold, copper alloys or any other combinations of these materials. Furthermore, the metal regions 222 may also comprise aluminum, if the electrical characteristics thereof are compatible with the requirements of the metallization system 250. Furthermore, a dielectric cap layer or etch stop layer 223 may be provided on the dielectric material 221 and the metal regions 222. It should be appreciated that the dielectric cap layer 223 may provide the required electromigration behavior of the metal regions 222B, while, in other cases, a dedicated conductive cap material may be formed on the core metal 222B, as will be explained later on in more detail.

The metallization layer 230 may comprise one or more dielectric materials, indicated by 231, in which metal regions 232 may be formed and may comprise any appropriate metal 232B, possibly in combination with a barrier material 232A. Furthermore, the metal regions 232 may represent metal lines 232M and/or vias 232V in order to connect to the metallization layer 220 in accordance with the circuit requirements of the device 200. With respect to the metal regions 232, the same criteria apply as previously given with respect to the metal region 222 and with respect to the semiconductor device 100. Similarly, a width of the metal lines 232W may be in the range of several hundred nanometers to less than one hundred nanometers, depending on the metallization level under consideration and the specific type of interconnect to be provided on the basis of the metal regions 232. For example, in some metallization levels, the parasitic capacitance between the individual metal lines 232M may have a significant influence on the overall electrical performance of the metallization system 250 and may thus require sophisticated dielectric materials, such as low-k materials (ultra low-k) with a dielectric constant of 3.0, 2.7 and even less. In other cases, the electrical resistance of the metal lines 232M may have the dominant influence on the electrical behavior of a certain metallization level and, therefore, an increased cross-sectional area of the metal lines 232M may be provided. For this purpose, a width 232W may be selected as large as possible and also a depth of the metal lines 232M may be increased, thereby, for instance, reducing the “height” of the vias 232V. At any rate, in sophisticated applications, a spacing 230W between neighboring metal lines 232M may no longer be compatible with the dielectric strength of the material 231, when having experienced a certain degree of damaging, for instance caused by CMP and the like, as previously explained. In other cases, generally, the dielectric strength of the material 231 may be sufficient for less critical areas, except for a portion 234, which may also be referred to as an area of critical electrical field strength or of maximum electrical field strength. As will be explained later on in more detail, a dielectric material of superior dielectric strength may be provided in the vicinity of the area 234, thereby enhancing the overall reliability of the metallization system 250.

The semiconductor device 200 as illustrated in FIG. 2a may be formed on the basis of similar process techniques as previously described with reference to the semiconductor device 100. That is, the metallization layers 220 and 230 may be formed on the basis of similar process techniques as previously described with reference to the metallization layers 120 and 130. Consequently, after forming the metal regions 232 in the dielectric material 231, an excess material 232E, which may comprise copper, a conductive barrier material and the like, may be removed by any appropriate planarization technique, such as CMP, electro CMP, electro etching and the like. Consequently, after the planarization process, the surface areas 231S and 232S of the dielectric material 231 and the metal regions 232 may be exposed. As discussed above, during the preceding process sequence, a damaged surface layer 231A may be created, which may have significantly less dielectric strength compared to the remaining material 231. According to one illustrative embodiment, the device 200 may be exposed to an etch process 202, for instance in the form of a plasma assisted etch process based on an appropriate etch chemistry for removing the material 231. It should be appreciated that a plurality of etch recipes are available as, for instance, similar etch chemistries may be used as are also applied during the patterning of the dielectric material 231. In other cases, a wet chemical etch ambient may be established in order to remove material of the layer 231 selectively to the metal regions 232. Also for this purpose, a plurality of etch recipes, for instance based on hydrofluoric acid and the like, may be available. In one illustrative embodiment, the etch process 202 may be performed so as to remove at least the damaged surface layer 231A, a thickness of which may be determined on the basis of measurements and the like. For instance, during the etch process 202, an average thickness of approximately 5-25 nm may be removed from the material 231, thereby providing a vertical offset between the dielectric material 231 and the surface 232S of the metal regions 232.

FIG. 2b schematically illustrates the semiconductor device 200 after the above-described process sequence. As illustrated, the surface 231S of the dielectric material 231 may be “lowered” to a height level 231H relative to a height level 232H of the surface 232S of the metal regions 232. It should be appreciated that the height levels 231H, 232H may vary across the semiconductor device 200 due to process-related fluctuations. However, at any rate, the material 231 may be recessed with respect to the metal regions 232, thereby forming corresponding recesses 231R. It should further be appreciated that the height levels 231H, 232H may be referred to any appropriate “reference plane,” such as a lower lying material layer, the substrate 201 and the like. Consequently, upon removing at least the damaged layer 231A (FIG. 2a), upper sidewall portions 232F of the metal regions 232 may be exposed, wherein a corner thereof may represent the area 234 of critical electrical field strength which is now vertically offset from the surface 231S.

FIG. 2c schematically illustrates the semiconductor device 200 in a further advanced manufacturing stage. In this state, a dielectric cap layer or etch stop layer 233 may be formed on the dielectric material 231 and on the metal regions 232, thereby providing metal confinement, etch stop capabilities, electromigration behavior and the like. As previously explained, a plurality of dielectric materials, such as silicon nitride, silicon carbide, nitrogen-containing silicon carbide and the like, or combinations thereof, may be efficiently used as an etch stop and cap material. Thus, the layer 233 may also be formed in the recesses 231R and may therefore reliably enclose the sidewalls 231F and thus the critical area 234. Since the dielectric material 233 may have an increased dielectric strength compared to the material 231 and in particular compared to any damaged portion thereof, such as the layer 231A (FIG. 2a), enhanced reliability may be obtained at the critical area 234. Moreover, in the embodiment shown, a further dielectric material 241 may be formed in the recesses 231R and on the etch stop layer 233 and thus above the metal regions 232. For example, the material 241 may represent the dielectric material of a further metallization layer 240, wherein the material 241 may represent a low-k dielectric material, or any other appropriate material, depending on the performance requirements of the metallization layer 240. Consequently, the recesses 231R may be reliably filled with a dielectric material so that the metal regions 232 are reliably embedded in a dielectric material and also any spaces between adjacent metal regions 232 are filled with an appropriate dielectric material, wherein, in particular in the vicinity of the critical area 234, superior dielectric strength may be accomplished compared to conventional strategies, as previously described with reference to FIGS. 1a and 1b.

The materials 233 and 241 may be formed on the basis of any well-established process technique, such as CVD for the one or more materials of the layer 233, while the one or more materials 241 may be deposited by spin-on techniques, CVD and the like.

Consequently, the further processing of the device 200 may be continued by patterning the material 241 and forming metal regions therein, as is, for instance, described with reference to the metallization layer 230.

FIG. 2d schematically illustrates the semiconductor device 200 according to further illustrative embodiments in which, prior to forming the recesses 231R, a conductive cap material 232C may be selectively formed on the core metal 232B in order to provide superior confinement and/or electromigration behavior. As is well known, a plurality of conductive materials, such as compounds including cobalt, tungsten, phosphorous and the like, may form, in combination with a copper material, a strong interface, thereby providing superior electromigration performance. The conductive cap material 232C may be formed on the basis of electrochemical deposition techniques, i.e., electroless plating, in which the dielectric material 231 may be in contact with electrolytes, catalyst materials and the like. Consequently, during the selective deposition of the cap material 232C, the degree of contamination may be increased, thereby even further reducing the dielectric strength of a surface portion of the material 231, such as the surface layer 231A described in FIG. 2a. Consequently, by recessing the material 231 after the electrochemical deposition of the material 232C, any negative influences of the preceding processes, for instance in the form of any incorporated metal residues and the like, may be reduced, while the cap material 232C may provide integrity of the core material 232B. Thereafter, the further processing may be continued, as is described with reference to FIG. 2c, i.e., the etch stop layer 233 is formed, wherein an increased degree of flexibility in selecting an appropriate material composition may be achieved since electromigration and copper confinement may be accomplished on the basis of the cap material 232C.

FIG. 2e schematically illustrates the semiconductor device 200 according to further illustrative embodiments in which a spacer layer 235 may be formed after recessing the dielectric material 231. The spacer layer 235 may be comprised of any appropriate material or materials in order to obtain the desired dielectric strength locally at the area 234, however without unduly affecting the overall capacitive response of the metallization layer 230. For example, the layer 235 may comprise silicon nitride, which may have a moderately high dielectric constant, which, however, may be acceptable when provided locally in the vicinity of the area 234. To this end, the device 200 may be exposed to an anisotropic etch process for etching the spacer layer 235 while maintaining material residues at the critical areas 234. For this purpose, any appropriate plasma assisted etch recipe may be applied.

FIG. 2f schematically illustrates the semiconductor device 200 with sidewall spacers 235S formed on the sidewalls 232F, thereby confining the critical area 234 with any appropriate material having a desired high dielectric strength without unduly affecting the overall electrical performance of the metallization layer 230. After providing the spacer elements 235S, the further processing may be continued by depositing an etch stop material, as previously discussed, and by refilling the recesses 231R, for instance with a dielectric material of the subsequent metallization level, as is also discussed above.

FIG. 2g schematically illustrates the semiconductor device 200 wherein a portion of the metallization layer 230 is illustrated. As shown, the spacer layer 235 may be provided as a combination of a first layer 235A, which may also be referred to as an etch stop liner, followed by a further dielectric material 235B, which may provide the superior dielectric behavior. For example, a combination of silicon dioxide and silicon nitride as the layers 235A, 235B may be applied and, thereafter, an anisotropic etch process may be applied in order to etch the layer 235B selectively with respect to the layer 235A. Consequently, the corresponding etch process may not unduly affect the dielectric material 231 and the metal region 232. Thereafter, exposed portions of the etch stop liner 235A may be efficiently removed from the metal region 232 and the dielectric material 231 on the basis of very selective and efficient wet chemical etch recipes, such as HF (hydrofluoric acid) and the like. During this removal process, the underlying materials may not be unduly affected.

FIG. 2h schematically illustrates the semiconductor device 200 according to illustrative embodiments in which the spacer layer 235 may be composed of more than two materials in order to provide a high degree of integrity of the materials 231 and 232B, while at the same time enabling an efficient etch process for forming spacer elements. In the embodiment shown, a first material layer 235C may be formed on the dielectric material 231 and on the metal regions 232, i.e., on the core metal 232B and the barrier material 232A. For example, the layer 235C may be selected in view of copper confinement and superior electromigration performance. For this purpose, silicon nitride may be used, wherein, due to a reduced thickness of the layer 235C, undue increase of the overall relative permittivity may be acceptable. For example, the layer 235C may be provided with a thickness of one to several nanometers. Next, the etch stop liner 235A may be provided, for instance in the form of silicon dioxide and the like, followed by the layer 235B having the desired dielectric strength. For example, the layer 235B may be provided in the form of silicon nitride and the like.

FIG. 2i schematically illustrates the semiconductor device 200 when exposed to the anisotropic etch ambient 204, thereby forming the spacer element 235S, while the etch process may be reliably stopped in the material 235A.

FIG. 2j schematically illustrates the semiconductor device 200 when exposed to a further etch ambient 205 which may be performed on the basis of hydrofluoric acid and the like, thereby efficiently removing the material 235A wherein the layer 235C may act as an efficient etch stop material. Consequently, the spacer elements 235S may be provided with the desired high dielectric strength without affecting the dielectric material 231 and core metal 232B. Moreover, the material 235C may provide superior metal confinement in metal regions 232 and electromigration performance, as discussed above. Thereafter, the further processing may be continued by depositing any further dielectric material, such as an additional etch stop material, followed by the dielectric material of the subsequent metallization level, as discussed above.

FIG. 2k schematically illustrates the semiconductor device 200 according to further illustrative embodiments in which the processing may be continued after removing any excess material for forming the metal regions 232 (FIG. 2a) by exposing the device 200 to a selective deposition ambient 206 in order to selectively form an additional metal material on the metal regions 232. In the embodiment shown, the deposition 206 may be performed as an electroless plating process in order to deposit a material 232D having substantially the same composition as the core metal 232B. Consequently, by depositing the material 232D, the overall cross-sectional area of the metal regions 232 may be efficiently increased by increasing the height of the metal regions 232, while a certain degree of corner rounding may also result in a less pronounced critical area 234. The electroless plating process may be performed on the basis of any appropriate process recipe, wherein the additional height, i.e., the thickness of the material 232D, may be selected from several nanometers to ten or more nanometers, depending on a desired vertical offset between the critical area 234 and the surface 231S. After the deposition process 206, corresponding cleaning processes may be applied which remove contaminants from the surface 231S, however, without requiring the removal of a specific portion of the material 231. In other cases, if desired, an additional material removal process may be applied, as is also previously described.

Consequently, the recesses 231R adjacent to the metal regions 232 may be provided on the basis of substantially the initial height of the material 231 by increasing the height of the metal regions 232, thereby also significantly increasing the overall conductivity thereof. Thereafter, the further processing may be continued by depositing a dielectric cap material, as previously explained. In other cases, an additional conductive cap material may be deposited on the portion 232D, if required.

FIG. 21 schematically illustrates a top view of a portion of the metallization layer 230. As shown, a certain degree of misalignment of the metal lines 232M with respect to the vias 232V may have occurred during the processing of the metallization layer 230. That is, the metal lines 232M may be laterally shifted by a certain distance, indicated as 236, with respect to a target position, indicated by the dashed lines. Consequently, the distance 230W between neighboring metal regions 232 may be reduced, thereby even further increasing the probability of creating dielectric breakdown events.

FIG. 2m schematically illustrates a cross-sectional view of the metallization layer 230 of FIG. 21 when configured in accordance with the principles disclosed herein. As illustrated, the critical area 234 may be confined by an appropriate material, such as the etch stop layer 233, as previously described, or by any other appropriate material, possibly in combination with the spacer element 235S, as described above with reference to FIGS. 2f-2j, so that, even for a reduced lateral distance 230W, a moderately high dielectric strength may be achieved. For instance, depending on the degree of misalignment, the recess 231R may be substantially completely filled with a material that may have a higher dielectric strength compared to the material 231. In the embodiment shown, the dielectric strength of the material 233 may be sufficient for a reliable operation of the device and the remaining volume of the recess 231R may be completely filled with a further dielectric material, such as the dielectric material 241 of the subsequent metallization level.

As a consequence, the present disclosure provides semiconductor devices and techniques in which the spacing between two neighboring metal regions may be reliably filled with a dielectric material, while a dielectric strength at a critical area of high electrical field strength may additionally be embedded in a material having superior dielectric strength. For this purpose, a recess may be provided, for instance, by removing a portion of the initial dielectric material and/or by increasing the height of the metal regions and, thereafter, the recess may be filled with any appropriate material, such as sidewall spacers and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a metallization system of a semiconductor device, the method comprising:
removing excess metal from a first dielectric material of a metallization layer by performing a planarization process so as to form insulated metal regions in said dielectric material;
removing at least a damaged portion of said dielectric material selectively to said insulated metal regions so as to form a recess adjacent to each of said insulated metal regions; and
filling said recess with a second dielectric material.

2. The method of claim 1, wherein filling said recess with a second dielectric material comprises forming an etch stop layer on an exposed surface of said first dielectric material and on said insulated metal regions.

3. The method of claim 2, wherein filling said recess with a second dielectric material further comprises forming a dielectric material of a second metallization layer on said etch stop layer.

4. The method of claim 1, wherein filling said recess with a second dielectric material comprises forming a dielectric material of a further metallization layer in said recess and above said insulated metal regions.

5. The method of claim 4, further comprising forming a conductive cap layer on said insulated metal regions prior to removing said at least a damaged portion of said first dielectric material.

6. The method of claim 1, further comprising forming a spacer element on exposed sidewall portions of said insulated metal regions in said recesses prior to filling said recesses with said second dielectric material.

7. The method of claim 6, wherein said spacer element is formed by using a material having a dielectric strength that is higher than a dielectric strength of said first dielectric material.

8. The method of claim 6, wherein forming said spacer element comprises forming an etch stop layer above said dielectric material after forming said recess and forming a spacer layer on said etch stop layer.

9. The method of claim 8, wherein said etch stop layer comprises a barrier material for suppressing metal diffusion.

10. The method of claim 8, further comprising removing portions of said etch stop layer not covered by said spacer element.

11. A method, comprising:
forming a recess between a first metal line and a second metal line, said first and second metal lines formed in a first dielectric material of a first metallization layer of a semiconductor device and comprising a conductive barrier material and a core metal;
filling said recess with a dielectric material; and
forming a second dielectric material of a second metallization layer above said first metallization layer.

12. The method of claim 11, wherein forming said recess comprises removing a metal-containing material from said first dielectric material by performing a planarization process and removing a surface portion of said first dielectric material selectively to said first and second metal lines.

13. The method of claim 11, wherein forming said recess comprises removing a metal-containing material from said first dielectric material by performing a planarization process so as to form said first and second metal lines, and selectively depositing a metal material of substantially the same composition as said core metal.

14. The method of claim 13, wherein said core metal comprises copper.

15. The method of claim 13, further comprising forming a conductive cap layer selectively on exposed areas of said metal material.

16. The method of claim 11, further comprising forming a dielectric cap layer in said recess and above said first and second metal lines prior to forming said second dielectric material.

17. The method of claim 16, wherein said dielectric cap layer is formed on said core metal of said first and second metal lines so as to confine said core metal.

18. The method of claim 11, further comprising forming a spacer layer on said first and second metal lines and in said recess and forming a spacer element from said spacer layer on sidewalls of said recess.

19. The method of claim 11, wherein filling said recess with a dielectric material comprises forming a dielectric etch stop layer on said first and second metal lines and in said recess and depositing said second dielectric material on said dielectric etch stop layer.

20. A semiconductor device, comprising:
a plurality of metal regions formed partially in a first dielectric material of a metallization layer, said metal regions having a core metal with a top surface that is positioned at a first height level, said first dielectric material extending to a second height level that is less than said first height level;
an etch stop material formed on said first dielectric material and on said plurality of metal regions; and
a second dielectric material formed on said etch stop material, said second dielectric material having a bottom surface at a third height level that is less than said first height level.

21. The device of claim 20, wherein a space between said plurality of metal regions is substantially completely filled by said first and second dielectric materials and by said etch stop material.

22. The device of claim 21, wherein said etch stop material is formed on said core metal.

23. The device of claim 20, wherein said first and second dielectric materials are low-k dielectric materials.

24. The device of claim 20, further comprising spacer elements formed on sidewall portions of said plurality of metal regions.

25. The device of claim 24, wherein said plurality of metal regions comprises a metal line having a width of approximately 100 nm or less.
